(19) United States
(12) Patent Application Publication
(10) Pub. No.: US 2024/0021238 A1
(43) Pub. Date: Jan. 18, 2024

(54) OPEN BIT-LINE TYPE SEMICONDUCTOR MEMORY DEVICE

(71) Applicant: FIDELIX CO., LTD., Seongnam-si (KR)

(72) Inventor: Jae Jin LEE, Gwangju-si (KR)

(73) Assignee: FIDELIX CO., LTD., Seongnam-si (KR)

(21) Appl. No.: 18/119,040

(22) Filed: Mar. 8, 2023

(30) Foreign Application Priority Data
Jul. 12, 2022 (KR) 10-2022-0085349

(51) Int. Cl. G11C 11/4097; G11C 11/4091

(52) U.S. Cl. CPC G11C 11/4097; G11C 11/4091

(57) ABSTRACT

In the semiconductor memory device of the disclosure, a half of the 1-st dummy memory cells of the 1-st dummy memory array and a half of the 2-nd dummy cells of the 2-nd dummy memory array can store data. In the semiconductor memory device of the disclosure, dummy memory cells corresponding to one normal memory array may be used to store data. As a result, according to the semiconductor memory device of the disclosure, the degree of integration may be greatly improved.

### CROSS-REFERENCE TO RELATED APPLICATION

This application claims priority to and the benefit of Korean Patent Application No. 2022-0085349, filed in the Korean Intellectual Property Office (KIPO) on Jul. 12, 2022, the disclosure of which is incorporated herein by reference in its entirety.

### BACKGROUND

### 1. Technical Field

The disclosure relates to a semiconductor memory device, and more specifically, to an open bit-line type semiconductor memory device for improving degree of integration.

### 2. Description of the Related Art

In general, a semiconductor memory device, such as DRAM, is configured to include memory cells. In each of the memory arrays, memory cells capable of storing data are disposed. Each of the memory cells may be accessed through control of a corresponding word line and bit line.

Semiconductor memory devices are highly integrated to store a large amount of data while having a small area required. The open bit line type semiconductor memory device requires a relatively smaller area than the folded bit line type semiconductor memory device having the same data storage capacity. Therefore, open bit line type semiconductor memory devices are widely used.

An open bit line type semiconductor memory device has a structure in which bit line sense amplifiers disposed between memory arrays are shared by bit lines of different memory arrays.

### SUMMARY

The disclosure is directed to an open bit-line type semiconductor memory device for improving degree of integration.

The technical objectives to be achieved by the disclosure are not limited to those described herein, and other technical objectives that are not mentioned herein would be clearly understood by a person skilled in the art from the description of the disclosure.

According to an aspect of the disclosure, there is provided a semiconductor memory device.

The semiconductor memory device according to an aspect of the disclosure comprises 1-st to n-th normal memory arrays arranged side by side a direction, wherein an i-th normal memory array includes a plurality of i-th normal memory cells arranged in a matrix structure including an i-th normal word line and a plurality of i-th normal bit lines, and the i-th normal word line is activated depending on the address value of a row address; a 1-st dummy memory array disposed adjacent to the 1-st normal memory array, and includes a plurality of 1-st dummy memory cells arranged in a matrix structure including a 1-st dummy word line and a plurality of 1-st dummy bit lines, wherein the 1-st dummy word line is activated depending on the address value of the row address; a 2-nd dummy memory array disposed adjacent to the n-th normal memory array, and includes a plurality of 2-nd dummy memory cells arranged in a matrix structure including a 2-nd dummy word line and a plurality of 2-nd dummy bit lines, wherein the 2-nd dummy word line is activated depending on the address value of the row address; and 1-st to (n+1)-th sense amplifier arrays, wherein the 1-st sense amplifier array includes a plurality of 1-st bit line sense amplifiers, the j-th sense amplifier array includes a plurality of j-th bit line sense amplifiers, and the (n+1)-th sense amplifier array includes a plurality of (n+1)-th bit line sense amplifiers. Each of the plurality of 1-st bit line sense amplifiers of the 1-st sense amplifier array is electrically connected to a corresponding 1-st dummy bit line of the 1-st dummy memory array and a corresponding 1-st normal bit line of the 1-st normal memory array. Each of the plurality of i-th bit line sense amplifiers of the i-th sense amplifier array is electrically connected to a corresponding (i-1)-th normal bit line of the (i−1)-th normal memory array and a corresponding i-th normal bit line of the i-th normal memory array. Each of the plurality of (n+1)-th bit line sense amplifiers of the (n+1)-th sense amplifier array is connected to a corresponding n-th normal bit line of the n-th normal memory array and a corresponding 2-nd dummy bit line of the 2-nd dummy memory array. ‘n’ is an odd number greater than or equal to 1, T is a natural number in a range of 1 to n, ‘j’ is a natural number in a range of 2 to n, and ‘p’ is a natural number in a range of 1 to (n+1)/2.

A plurality of (2p-1)-th bit line sense amplifiers of a (2p-1)-th sense amplifier array may be driven to transmit and receive data with a 1-st data input/output pad.

A plurality of (2p)-th bit line sense amplifiers of a (2p)-th sense amplifier array may be driven to transmit and receive data with a 2-nd data input/output pad.

the 1-st dummy word line of the 1-st dummy memory array and the 2-nd dummy word line of the 2-nd dummy memory array may be selected in response to the address value of a same row address.

According to other aspect of the disclosure, there is provided a semiconductor memory device.

The semiconductor memory device according to other aspect of the disclosure comprises a 1-st to an n-th normal memory arrays arranged side by side in a direction, wherein an i-th normal memory array includes a plurality of i-th normal memory cells arranged in a matrix structure including an i-th normal word line and a plurality of i-th normal bit lines, and the i-th normal word line is activated depending on the address value of a row address; a 1-st dummy memory array disposed adjacent to the 1-st normal memory array, and includes a plurality of 1-st dummy memory cells arranged in a matrix structure including a 1-st dummy word line and a plurality of 1-st dummy bit lines, wherein the 1-st dummy word line is activated depending on the address value of the row address; a 2-nd dummy memory array disposed adjacent to the n-th normal memory array, and includes a plurality of 2-nd dummy memory cells arranged in a matrix structure including a 2-nd dummy word line and a plurality of 2-nd dummy bit lines, wherein the 2-nd dummy word line is activated depending on the address value of the row address; and 1-st to (n+1)-th sense amplifier arrays, wherein the 1-st sense amplifier array includes a plurality of 1-st bit line sense amplifiers, the j-th sense amplifier array includes a plurality of j-th bit line sense amplifiers, and the (n+1)-th sense amplifier array includes a plurality of (n+1)-th bit line sense amplifiers. Each of the plurality of 1-st bit line sense amplifiers of the 1-st sense amplifier array is electrically connected to a corresponding 1-st dummy bit line of the 1-st dummy memory array and a corresponding 1-st normal bit line of the 1-st normal memory array. Each of the plurality of i-th bit line sense amplifiers of the i-th sense amplifier array is electrically connected to a corresponding (i-1)-th normal bit line of the (i−1)-th normal memory array and a corresponding i-th normal bit line of the i-th normal memory array. Each of the plurality of (n+1)-th bit line sense amplifiers of the (n+1)-th sense amplifier array is electrically connected to a corresponding n-th normal bit line of the n-th normal memory array and a corresponding 2-nd dummy bit line of the 2-nd dummy memory array. ‘n’ is an even number greater than or equal to 2, T is a natural number from 1 to n, ‘j’ is a natural number from 2 to n, and ‘p’ is a natural number from 1 to n/2.

A plurality of (2p-1)-th bit line sense amplifiers of a (2p-1)-th sense amplifier array may be driven to transmit and receive data with a 1-st data input/output pad.

A plurality of (2p)-th bit line sense amplifiers of a (2p)-th sense amplifier array may be driven to transmit and receive data with a 2-nd data input/output pad.

Each of the plurality of (n+1)-th bit line sense amplifiers of the (n+1)-th sense amplifier array may be driven to transmit and receive data with the 1-st data input/output pad in response to selection of one of the n-th normal bit lines of the n-th normal memory array, and driven to transmit and receive data with the 2-nd data input/output pad in response to selection of one of the 2-nd dummy bit lines of the 2-nd dummy memory array.

The 1-st dummy word line of the 1-st dummy memory array and the 2-nd dummy word line of the 2-nd dummy memory array may be selected in response to the address value of a same row address.

The semiconductor memory device may further include a bottom data line disposed between the n-th normal memory array and the 2-nd dummy memory array, and transmitting and receiving data with the plurality of (n+1)-th bit line sense amplifiers of the (n+1)-th sense amplifier array; a 1-st global data line transmitting and receiving data with the 1-st data input/output pad; a 2-nd global data line transmitting and receiving data with the 2-nd data input/output pad; and a global switching part. The global switching part may be driven to transmit and receive data between the bottom data line and the 1-st global data line in response to selection of the n-th normal word line of the n-th normal memory array, and driven to transmit and receive data between the bottom data line and the 2-nd global data line in response to selection of the 2-nd dummy word line of the 2-nd dummy memory array.

The semiconductor memory device further may include 1-st to 2-nd bottom data line disposed between the n-th normal memory array and the 2-nd dummy memory array. The 1-st bottom data line may transmit and receive data with the 1-st data input/output pad, and the 2-nd bottom data line may transmit and receive data with the 2-nd data input/output pad, each of the plurality of (n+1)-th bit line sense amplifiers of the (n+1)-th sense amplifier array may be driven to transmit and receive data with the 1-st bottom data line in response to selection of one of the n-th normal bit lines of the n-th normal memory array, and driven to transmit and receive data with the 2-nd bottom data line in response to selection of one of the 2-nd dummy bit lines of the 2-nd dummy memory array.

According to another aspect of the disclosure, there is provided a semiconductor memory device.

The semiconductor memory device according to another aspect of the disclosure comprises 1-st to n-th normal memory arrays arranged side by side in a direction, wherein an i-th normal memory array includes a plurality of i-th normal memory cells arranged in a matrix structure including an i-th normal word line and a plurality of i-th normal bit lines, and the i-th normal word line is activated depending on the address value of a row address; a 1-st dummy memory array disposed adjacent to the 1-st normal memory array, and includes a plurality of 1-st dummy memory cells arranged in a matrix structure including a 1-st dummy word line and a plurality of 1-st dummy bit lines, wherein the 1-st dummy word line is activated depending on the address value of the row address; a 2-nd dummy memory array disposed adjacent to the n-th normal memory array, and includes a plurality of 2-nd dummy memory cells arranged in a matrix structure including a 2-nd dummy word line and a plurality of 2-nd dummy bit lines, wherein the 2-nd dummy word line is activated depending on the address value of the row address; and 1-st to (n+1)-th sense amplifier arrays, wherein the 1-st sense amplifier array includes a plurality of 1-st bit line sense amplifiers, the j-th sense amplifier array includes a plurality of j-th bit line sense amplifiers, and the (n+1)-th sense amplifier array includes a plurality of (n+1)-th bit line sense amplifiers. Each of the plurality of 1-st bit line sense amplifiers of the 1-st sense amplifier array is electrically connected to a corresponding 1-st dummy bit line of the 1-st dummy memory array and a corresponding 1-st normal bit line of the 1-st normal memory array. Each of the plurality of i-th bit line sense amplifiers of the i-th sense amplifier array is electrically connected to a corresponding (i-1)-th normal bit line of the (i−1)-th normal memory array and a corresponding i-th normal bit line of the i-th normal memory array. Each of the plurality of (n+1)-th bit line sense amplifiers of the (n+1)-th sense amplifier array is electrically connected to a corresponding n-th normal bit line of the n-th normal memory array and a corresponding 2-nd dummy bit line of the 2-nd dummy memory array, ‘n’ is a natural number greater than or equal to 2, T is a natural number from 1 to n, and ‘j’ is a natural number from 2 to n.

The 1-st dummy word line of the 1-st dummy memory array and the 2-nd dummy word line of the 2-nd dummy memory array may be selected in response to the address value of a same row address.

The semiconductor memory device may further comprise 1-st and 2-nd bottom data lines; ‘n/2’ local switch part; 1-st and 2-nd bottom sense amplifiers; and a 1-st global data line and a 2-nd global data line.

The local switching part may be driven for the 1-st bottom data line to transmit and receive data with the plurality of (n+1) bit line sense amplifiers in response to selection of the i-th normal word line of the i-th normal memory array.

The local switching part may be driven for the 2-nd bottom data line to transmit and receive data with the (n+1) bit line sense amplifiers in response to selection of the i-th dummy word line of the i-th dummy memory array.

In the semiconductor memory device of the disclosure having the above configuration, 1/2 of the 1-st dummy memory cells of the 1-st dummy memory array and 1/2 of the 2-nd dummy memory cells of the 2-nd dummy memory array may be used to store data. That is, in the semiconductor memory device of the disclosure, dummy memory cells corresponding to one normal memory array are used to store data. As a result, according to the semiconductor memory device of the disclosure, the degree of integration is greatly improved.

### BRIEF DESCRIPTION OF THE DRAWINGS

The above and other objects, features and advantages of the disclosure will become more apparent to those skilled in the art by describing in detail embodiments thereof with reference to the accompanying drawings, in which:

FIG. 1 is a schematic drawing illustrating a semiconductor memory device according to a first embodiment of the disclosure;

FIG. 2 is a schematic timing diagram for explaining activation timings of 1-st to 3-rd normal word lines and dummy word lines in the semiconductor memory device of FIG. 1;

FIG. 3 is a schematic drawing illustrating a semiconductor memory device according to a second embodiment of the disclosure;

FIG. 4 is a schematic drawing illustrating the global switching part of FIG. 3;

FIG. 5 is a schematic drawing illustrating a semiconductor memory device according to a third embodiment of the disclosure; and

FIG. 6 is a schematic drawing illustrating one of the local switching parts of FIG. 5.

### DETAILED DESCRIPTION OF THE EMBODIMENTS

Embodiments of the disclosure will be described in detail below with reference to the accompanying drawings. While the disclosure is shown and described in connection with embodiments thereof, it will be apparent to those skilled in the art that various modifications can be made without departing from the spirit and scope of the disclosure. Thus, the scope of the disclosure is not limited to the following embodiments.

The terminology used herein is for the purpose of describing embodiments only and is not intended to be limiting of the invention. As used herein, the singular forms such as “a” and “an” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in detail with reference to the accompanying drawings.

### First Embodiment

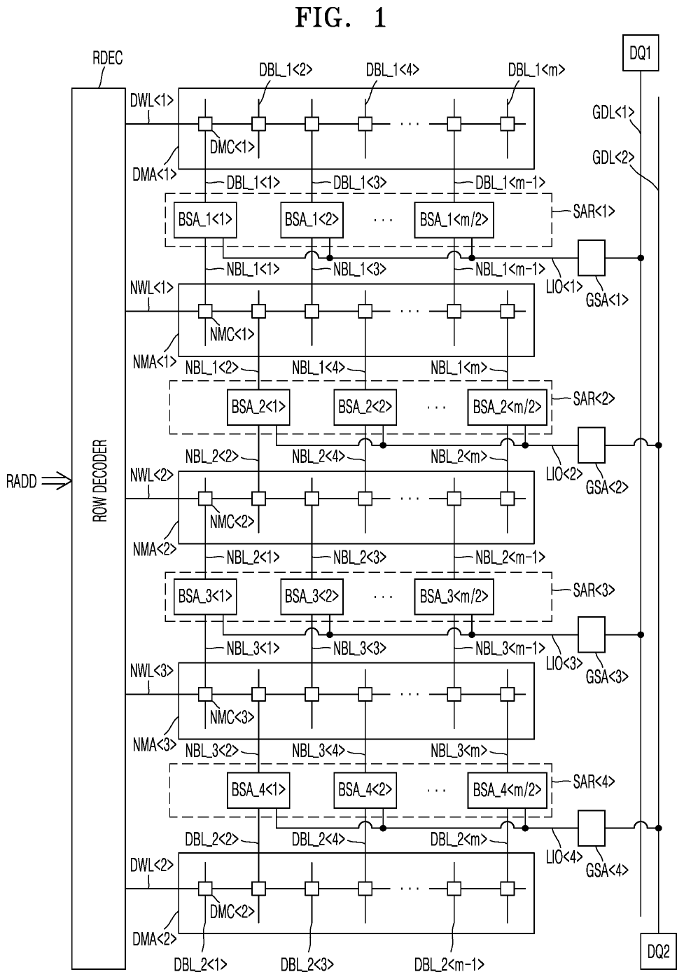

FIG. 1 is a schematic drawing illustrating a semiconductor memory device according to a first embodiment of the disclosure. Referring to FIG. 1, the semiconductor memory device of the first embodiment may include ‘n’ normal memory arrays. In the first embodiment, ‘n’ may be an odd number greater than or equal to 1, and may be ‘3’ in an embodiment.

For example, the semiconductor memory device of FIG. 1 may include 1-st to 3-rd normal memory arrays NMA<1:3>, a 1-st dummy memory array DMA<1>, a 2-nd dummy memory array DMA<2>, and 1-st to 4-th sense amplifier arrays SAR<1:4>.

For example, 1-st to 3-rd normal memory arrays NMA<1:3> may be arranged side by side in serial order in a direction (e.g., a vertical direction in FIG. 1). The 1-st dummy memory array DMA<1> may be disposed adjacent to an outer side (upper side in FIG. 1) of the 1-st normal memory array NMA<1>, and the 2-nd dummy memory array DMA<2> may be disposed adjacent to an opposite outer side (lower side in FIG. 1) of the 3-rd normal memory array NMA<3>.

In each of the 1-st to the 3-rd normal memory arrays NMA<1:3>, the 1-st dummy memory array DMA<1>, and the 2-nd dummy memory array DMA<2>, one or more word lines may be disposed.

However, for ease of illustration, one word line is representatively shown and described in each of the 1-st to the 3-rd normal memory array NMA<1:3>, the 1-st dummy memory array DMA<1>, and the 2-nd dummy memory array DMA<2>.

An i-th normal memory array NMA<i> may include i-th normal memory cells NMC<i>arranged on a matrix structure including (or consisting of) an i-th normal word line NWL<i> and ‘In’ i-th normal bit lines NBLi<1:m>. In an embodiment, ‘i’ may be a natural number from 1 to 3, and ‘In’ may be an even number greater than or equal to 2. For example, the i-th normal word line NWL<i>may be activated depending on the address value of a row address RADD. However, the embodiments are not limited thereto.

The 1-st dummy memory array DMA<1> may include 1-st dummy memory cells DMC<1>arranged on a matrix structure including a 1-st dummy word line DWL<1> and ‘na’ 1-st dummy bit lines DBL_1<1:m>. For example, the 1-st dummy word line DWL<1> may be activated depending on the address value of the row address RADD.

The 2-nd dummy memory array DMA<2> may include 2-nd dummy memory cells DMC<2>arranged on a matrix structure including a 2-nd dummy word line DWL<2> and ‘m’ 2-nd dummy bit lines DBL_2<1:m>. For example, the 2-nd dummy word line DWL<2> may be activated depending on the address value of the row address RADD.

The 1-st amplifier array SAR<1> may include ‘m/2’ 1-st bit line sense amplifiers BSA_1, the j-th sense amplifier array SAR<j> may include ‘m/2’ 2-nd bit line sense amplifiers BSA_j. In an embodiment, ‘j’ may be a natural number from 2 to 3. The 4-th amplifier array SAR<4> may include ‘m/2’ 4-th bit line sense amplifiers BSA_4.

For example, each of the 1-st bit line sense amplifiers BSA_1 of the 1-st sense amplifier array SAR<1> may be connected to a corresponding 1-st dummy bit line DBL_1 of the 1-st dummy memory array DMA<1> and a corresponding 1-st normal bit line NBL_1 of the 1-st normal memory array NMA<1>.

For example, each of the 1-st bit line sense amplifiers BSA_1 of the 1-st sense amplifier array SAR<1> may be driven to transmit and receive data with the corresponding 1-st dummy bit line DBL_1 of the 1-st dummy memory array DMA<1> in case that the 1-st dummy word line DWL<1> is activated.

Each of the 1-st bit line sense amplifiers BSA_1 of the 1-st sense amplifier array SAR<1> may be driven to transmit and receive data with the corresponding 1-st normal bit line NBL_1 of the 1-st normal memory array NMA<1> in case that the 1-st normal word line NWL<1> is activated.

For example, in case that the 1-st dummy word line DWL<1> is activated, the 1-st bit line sense amplifier BSA_1<2>disposed second from the left of the 1-st sense amplifier array SAR<1> may be driven to amplify data transmitted and received with the 1-st dummy bit line DBL_1<3>disposed third from the left of the 1-st dummy memory array DMA<1>.

In case that the 1-st normal word line NWL<1> is activated, the 1-st bit line sense amplifier BSA_1<2>disposed second from the left of the 1-st sense amplifier array SAR<1> may be driven to amplify data transmitted and received with the 1-st normal bit line NBL l<3>disposed third from the left of the 1-st normal memory array NMA<1>.

Each of the j-th bit line sense amplifiers BSA_j of a j-th sense amplifier array SAR<j> may be connected to a corresponding (j-1)-th normal bit line NBL j-1 of the (j-1)-th normal memory array NMA<j-1> and a corresponding j-th normal bit line NBL_j of the j-th normal memory array NMA<j>.

For example, each of the j-th bit line sense amplifiers BSA_j of a j-th sense amplifier array SAR<j> may be driven to transmit and receive data with the corresponding (j-1)-th normal bit line NBL j-1 of the (j-1)-th normal memory array NMA<j-1> in case that a (j-1)-th normal word line NWL<j-1> is activated.

Each of the j-th bit line sense amplifiers BSA_j of a j-th sense amplifier array SAR<j> may be driven to transmit and receive data with the corresponding j-th normal bit line NBL_j of the j-th normal memory array NMA<j> in case that a j-th normal word line NWL<j> is activated.

For example, in case that the 1-st normal word line NWL<1> is activated, the 2-nd bit line sense amplifier BSA_2<2>disposed second from the left of the 2-nd sense amplifier array SAR<2> may be driven to amplify data transmitted and received with the 1-st normal bit line NBL l<4>disposed forth from the left of the 1-st normal memory array NMA<1>.

Each of the 4-th bit line sense amplifiers BSA_4 of the 4-th sense amplifier array SAR<4> may be connected to a corresponding 3-th normal bit line NBL_3 of the 3-th normal memory array NMA<3> and a corresponding 2-nd dummy bit line DBL_2 of the 2-nd dummy memory array DMA<2>.

For example, each of the 4-th bit line sense amplifiers BSA 4 of the 4-th sense amplifier array SAR<4> may be driven to transmit and receive data with the corresponding 3-th normal bit line NBL_3 of the 3-th normal memory array NMA<3> in case that the 3-rd normal word line NWL<3> is activated.

Each of the 4-th bit line sense amplifiers BSA_4 of the 4-th sense amplifier array SAR<4> may be driven to transmit and receive data with the corresponding 2-nd dummy bit line DBL_2 of the 2-nd dummy memory array DMA<2> in case that the 2-nd dummy word line DWL<2> is activated.

For example, in case that the 3-rd normal word line NWL<3> is activated, the 4-th bit line sense amplifier BSA_4<2>disposed second from the left of the 4-th sense amplifier array SAR<4> may be driven to amplify data transmitted and received with the 3-th normal bit line NBL 3<4>disposed forth from the left of the 3-th normal memory array NMA<3>.

In case that the 2-nd dummy word line DWL<2> is activated, the 4-th bit line sense amplifier BSA_4<2>disposed second from the left of the 4-th sense amplifier array SAR<4> may be driven to amplify data transmitted and received with the 32-nd dummy bit line DBL_2<4>disposed forth from the left of the 2-nd dummy memory array DMA<2>.

In this embodiment, any one of the 1-st bit line sense amplifiers BSA_1 of the 1-st sense amplifier array SAR<1> may be selected as a column address (not shown).

In case that the 1-st dummy memory array DMA<1> or the 1-st normal memory array NMA<1> is selected according to the row address RADD, the selected 1-st bit line sense amplifier BSA_1 may be driven to transmit and receive data with the 1-st data input/output pad DQ1 via a 1-st local data line LI0<1>, a 1-st global bit line sense amplifier GSA<1> and a 1-st global data line GDL<1>.

The 1-st global bit line sense amplifier GSA<1> may amplify data transmitted and received between the 1-st local data line LIO<1> and the 1-st global data line GDL<1>.

Any one of the 2-nd bit line sense amplifiers BSA_2 of the 2-nd sense amplifier array SAR<2> may be selected as a column address (not shown).

In case that the 1-st normal memory array NMA<1> or the 2-nd normal memory array NMA<2> is selected according to the row address RADD, the selected 2-nd bit line sense amplifier BSA 2 may be driven to transmit and receive data with the 2-nd data input/output pad DQ2 via a 2-nd local data line LIO<2>, a 2-nd global bit line sense amplifier GSA<2> and a 2-nd global data line GDL<2>.

The 2-nd global bit line sense amplifier GSA<2> may amplify data transmitted and received between the 2-nd local data line LIO<2> and the 2-nd global data line GDL<2>.

Any one of the 3-rd bit line sense amplifiers BSA_3 of the 3-rd sense amplifier array SAR<3> may be selected as a column address (not shown).

In case that the 2-nd normal memory array NMA<2> or the 3-rd normal memory array NMA<3> is selected according to the row address RADD, the selected 3-rd bit line sense amplifier BSA_3 may be driven to transmit and receive data with the 1-st data input/output pad DQ1 via a 3-rd local data line LIO<3>, a 3-rd global bit line sense amplifier GSA<3> and the 1-st global data line GDL<1>.

The 3-rd global bit line sense amplifier GSA<3> may amplify data transmitted and received between the 3-rd local data line LIO<3> and the 1-st global data line GDL<1>.

Any one of the 4-th bit line sense amplifiers BSA_4 of the 4-th sense amplifier array SAR<4> may be selected as a column address (not shown).

In case that the 3-rd normal memory array NMA<3> or the 2-nd dummy memory array DMA<2> is selected according to the row address RADD, the selected 4-th bit line sense amplifier BSA_4 may be driven to transmit and receive data with the 2-nd data input/output pad DQ2 via a 4-th local data line LIO<4>, a 4-th global bit line sense amplifier GSA<4> and the 2-nd global data line GDL<2>.

The 4-th global bit line sense amplifier GSA<4> may amplify data transmitted and received between the 4-th local data line LIO<4> and the 2-nd global data line GDL<2>.

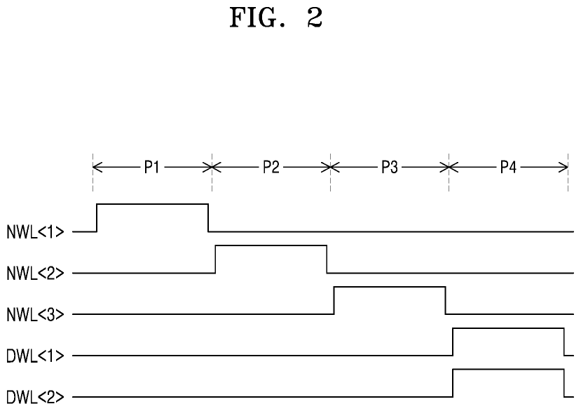

The row address RADD may include multiple bits. The row decoder RDEC may decode the row address RADD to selectively activate the 1-st to the 3-rd normal word lines NWL<1:3> and the dummy word lines DWL, as shown in FIG. 2.

In FIG. 2, sections P1 to P4 refer to sections in which the address values of the row addresses RADD are different from each other.

It can be seen that the 1-st dummy word line DWL<1> and the 2-nd dummy word line DWL<2>are both activated at the same address value of the row address RADD in period P4.

In summary, in the semiconductor memory device of the first embodiment, a half of the 1-st dummy bit lines DBL_1 of the 1-st dummy memory array DMA<1> may be connected to the 1-st bit line sense amplifiers BSA_1 of the 1-st sense amplifier array SAR<1>, and a half of the 2-nd dummy bit lines DBL_2 of the 2-nd dummy memory array DMA<2> may be connected to the 4-th bit line sense amplifiers BSA_4 of the 4-th sense amplifier array SAR<4>.

In other words, the half of the 1-st dummy memory cells DMC<1> of the 1-st dummy memory array DMA<1> and the half of the 2-nd dummy cells DMC<2>of the 2-nd dummy memory array DMA<2>can store data.

For example, in the semiconductor memory device of the first embodiment, dummy memory cells DMC corresponding to one normal memory array NMA may be used to store data. As a result, according to the semiconductor memory device of the first embodiment, the degree of integration may be greatly improved.

In the first embodiment, ‘n’ may be an odd number greater than or equal to 1 as described above.

However, the technical idea of the disclosure can also be implemented by another embodiment. For example, in the second embodiment, ‘n’ may be an even number greater than or equal to 2.

### Second Embodiment

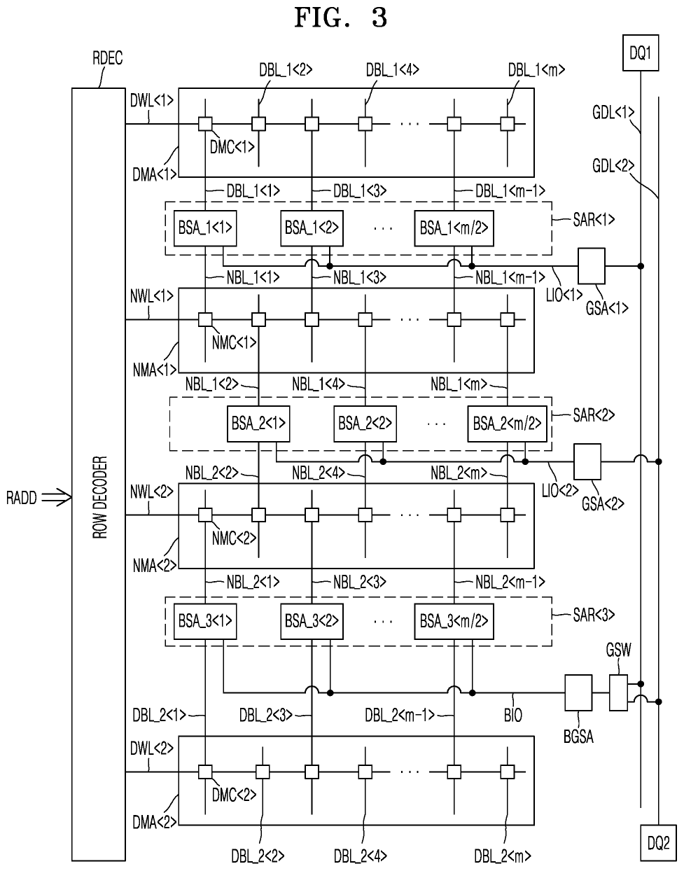

FIG. 3 is a schematic drawing illustrating a semiconductor memory device according to a second embodiment of the disclosure. Referring to FIG. 3, the semiconductor memory device of the second embodiment includes ‘n’ normal memory arrays. In the second embodiment, ‘n’ may be an even number greater than or equal to 2, and is ‘2’ in this specification.

For example, the semiconductor memory device of FIG. 3 may include 1-st to 2-nd normal memory arrays NMA<1:2>, a 1-st dummy memory array DMA<1>, a 2-nd dummy memory array DMA<2>, and 1-st to 3-rd sense amplifier arrays SAR<1:3>.

For example, a 1-st to a 2-nd normal memory array NMA<1:2> may be arranged side by side in serial order in a direction (e.g., a vertical direction in FIG. 3). The 1-st dummy memory array DMA<1> may be disposed adjacent to an outer side (upper side in FIG. 3) of the 1-st normal memory array NMA<1>, and the 2-nd dummy memory array DMA<2> may be disposed adjacent to an opposite outer side (lower side in FIG. 3) of the 2-nd normal memory array NMA<2>.

In each of the 1-st to 2-nd normal memory arrays NMA<1:2>, the 1-st dummy memory array DMA<1>, and the 2-nd dummy memory array DMA<2>, one or more word lines may be disposed.

However, for ease of illustration, one word line is representatively shown and described in each of the 1-st to 2-nd normal memory arrays NMA<1:2>, the 1-st dummy memory array DMA<1>, and the 2-nd dummy memory array DMA<2>.

An i-th normal memory array NMA<i> may include i-th normal memory cells NMC<i>arranged on a matrix structure including an i-th normal word line NWL<i> and ‘m’ i-th normal bit lines NBL_i<1:m>. Here, T may be a natural number from 1 to 2, and ‘m’ may be an even number greater than or equal to 2. For example, the i-th normal word line NWL<i> may be activated depending on the address value of a row address RADD.

The 1-st dummy memory array DMA<1> may include 1-st dummy memory cells DMC<1>arranged on a matrix structure including a 1-st dummy word line DWL<1> and ‘m’ 1-st dummy bit lines DBL_1<1:m>. For example, the 1-st dummy word line DWL<1> may be activated depending on the address value of the row address RADD.

The 2-nd dummy memory array DMA<2> may include 2-nd dummy memory cells DMC<2>arranged on a matrix structure including a 2-nd dummy word line DWL<2> and ‘m’ 2-nd dummy bit lines DBL_2<1:m>. For example, the 2-nd dummy word line DWL<2> may be activated depending on the address value of the row address RADD.

The 1-st amplifier array SAR<1> may include ‘m/2’ 1-st bit line sense amplifiers BSA_1, the 2-nd amplifier array SAR<2> may include ‘m/2’ 2-nd bit line sense amplifiers BSA_2, and 3-rd amplifier array SAR<3> may include ‘m/2’ 3-rd bit line sense amplifiers BSA_3.

For example, each of the 1-st bit line sense amplifiers BSA_1 of the 1-st sense amplifier array SAR<1> may be connected to a corresponding 1-st dummy bit line DBL_1 of the 1-st dummy memory array DMA<1> and a corresponding 1-st normal bit line NBL_1 of the 1-st normal memory array NMA<1>.

For example, each of the 1-st bit line sense amplifiers BSA_1 of the 1-st sense amplifier array SAR<1> may be driven to transmit and receive data with the corresponding 1-st dummy bit line DBL_1 of the 1-st dummy memory array DMA<1> in case that the 1-st dummy word line DWL<1> is activated.

Each of the 1-st bit line sense amplifiers BSA_1 of the 1-st sense amplifier array SAR<1> may be driven to transmit and receive data with the corresponding 1-st normal bit line NBL_1 of the 1-st normal memory array NMA<1> in case that the 1-st normal word line NWL<1> is activated.

Each of the 2-nd bit line sense amplifiers BSA_2 of a 2-nd sense amplifier array SAR<2> may be connected to a corresponding 1-st normal bit line NBL_1 of the j-st normal memory array NMA<1> and a corresponding 2-nd normal bit line NBL_2 of the 2-nd normal memory array NMA<2>.

For example, each of the 2-nd bit line sense amplifiers BSA_2 of a 2-nd sense amplifier array SAR<2> may be driven to transmit and receive data with the corresponding 1-st normal bit line NBL_1 of the 1-st normal memory array NMA<1> in case that a 1-st normal word line NWL<1> is activated.

Also, each of the 2-nd bit line sense amplifiers BSA_2 of a 2-nd sense amplifier array SAR<2> may be driven to transmit and receive data with the corresponding 2-nd normal bit line NBL_2 of the 2-nd normal memory array NMA<2> in case that a 2-nd normal word line NWL<2> is activated.

Each of the 3-rd bit line sense amplifiers BSA_3 of the 3-rd sense amplifier array SAR<3> may be connected to a corresponding 2-nd normal bit line NBL_2 of the 2-nd normal memory array NMA<2> and a corresponding 2-nd dummy bit line DBL_2 of the 2-nd dummy memory array DMA<2>.

For example, each of the 3-rd bit line sense amplifiers BSA_3 of the 3-rd sense amplifier array SAR<3> may be driven to transmit and receive data with the corresponding 2-nd normal bit line NBL_2 of the 2-nd normal memory array NMA<2> in case that the 2-nd normal word line NWL<2> is activated.

Each of the 3-rd bit line sense amplifiers BSA_3 of the 3-rd sense amplifier array SAR<3> may be driven to transmit and receive data with the corresponding 2-nd dummy bit line DBL_2 of the 2-nd dummy memory array DMA<2> in case that the 2-nd dummy word line DWL<2> is activated.

In this embodiment, any one of the 1-st bit line sense amplifiers BSA_1 of the 1-st sense amplifier array SAR<1> may be selected as a column address (not shown).

In case that the 1-st dummy memory array DMA<1> or the 1-st normal memory array NMA<1> is selected according to the row address RADD, the selected 1-st bit line sense amplifier BSA_1 may be driven to transmit and receive data with the 1-st data input/output pad DQ1 via a 1-st local data line LI0<1>, a 1-st global bit line sense amplifier GSA<1> and a 1-st global data line GDL<1>.

The 1-st global bit line sense amplifier GSA<1> may amplify data transmitted and received between the 1-st local data line LIO<1> and the 1-st global data line GDL<1>.

Any one of the 2-nd bit line sense amplifiers BSA_2 of the 2-nd sense amplifier array SAR<2> may be selected as a column address (not shown).

In case that the 1-st normal memory array NMA<1> or the 2-nd normal memory array NMA<2> is selected according to the row address RADD, the selected 2-nd bit line sense amplifier BSA_2 may be driven to transmit and receive data with the 2-nd data input/output pad DQ2 via a 2-nd local data line LIO<2>, a 2-nd global bit line sense amplifier GSA<2> and a 2-nd global data line GDL<2>.

The 2-nd global bit line sense amplifier GSA<2> may amplify data transmitted and received between the 2-nd local data line LIO<2> and the 2-nd global data line GDL<2>.

The semiconductor memory device according to the second embodiment may further include a bottom data line BIO, a 1-st global data line GDL<1>, a 2-nd global data line GDL<2>, and a global switching part (or global switching unit) GSW.

The bottom data line BIO may be disposed between the 2-nd normal memory array NMA<2> and the 2-nd dummy memory array DMA<2>. Bottom data line BIO may transmit and receive data with the 3-rd bit line sense amplifiers BSA_3 of the 3-rd sense amplifier array SAR<3>.

The 1-st global data line GDL<1> may transmit and receive data with the 1-st data input/output pad DQ1, and the 2-nd global data line GDL<2> may transmit and receive data with the 2-nd data input/output pad DQ2.

The global switching part GSW may be driven so that one of the 1-st global data line GDL<1> and the 2-nd global data line GDL<2> may transmit and receive data with a bottom sense amplifier BGSA. Here, the bottom sense amplifier BGSA may amplify data of the bottom data line BIO.

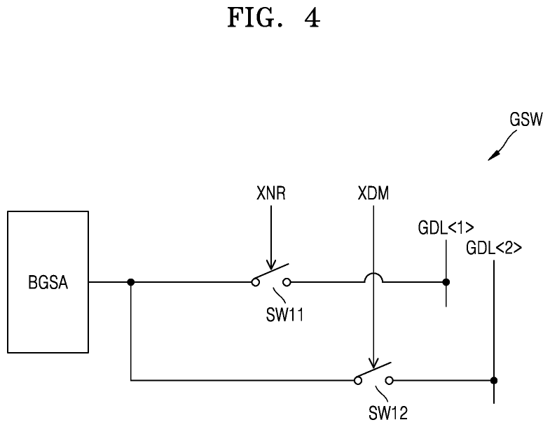

FIG. 4 is a schematic drawing illustrating the global switching part GSW of FIG. 3. Referring to FIG. 4, the global switching part GSW may include 1-st and 2-nd global switches SW11 and SW12.

The 1-st global switch SW11 may be driven in response to activation of the normal signal XNR for the 1-st global data line GDL<1> to transmit and receive data with the bottom sense amplifier BGSA. For example, the normal signal XNR may be activated according to the address value of the row address RADD at which the 2-nd normal word line NWL<2> of the 2-nd normal memory array NMA<2>may be activated.

The 2-nd global switch SW12 may be driven in response to activation of the dummy signal XDM for the 2-nd global data line GDL<2> to transmit and receive data with the bottom sense amplifier BGSA. For example, the dummy signal XDM may be activated according to the address value of the row address RADD at which the 2-nd dummy word line DWL<2> of the 2-nd dummy memory array DMA<2> may be activated.

As a result, the global switching part GSW may be driven to transmit and receive data between the bottom data line BIO and the 1-st global data line GDL<1>in response to selection of the 2-nd normal word line NWL<2> of the 2-nd normal memory array NMA<2>.

The global switching part GSW may be driven to transmit and receive data between the bottom data line BIO and the 2-nd global data line GDL<2> in response to selection of the 2-nd dummy word line DWL<2> of the 2-nd dummy memory array DMA<2>.

Referring again to FIG. 3, any one of the 3-rd bit line sense amplifiers BSA_3 of the 3-rd sense amplifier array SAR<3> may be selected as a column address (not shown).

In case that the 2-nd normal memory array NMA<2> is selected according to the row address RADD, the selected 3-rd bit line sense amplifier BSA_3 may be driven to transmit and receive data with the 1-st data input/output pad DQ1 via the bottom data line BIO, the bottom sense amplifier BGSA, the global switch GSW and the 1-st global data line GDL<1>.

In case that the 2-nd dummy memory array DMA<2> is selected according to the row address RADD, the selected 3-rd bit line sense amplifier BSA_3 may be driven to transmit and receive data with the 2-nd data input/output pad DQ2 via the bottom data line BIO, the bottom sense amplifier BGSA, the global switch GSW and the 2-nd global data line GDL<2>.

The bottom sense amplifier BGSA may amplify data transmitted and received between the bottom data line BIO and one of the 1-st global data line GDL<1> and the 2-nd global data line GDL<2>selected according to the address value of the row address RADD.

The row address RADD may include a plurality of bits. The row decoder RDEC may decode the row address RADD to selectively activate the 1-st to the 2-nd normal word lines NVVL<1:2> and the dummy word lines DWL.

The 1-st dummy word line DWL<1> and the 2-nd dummy word line DWL<2> may both be activated at the same address value of the row address RADD. In this case, a phenomenon in which data of the 1-st dummy memory array DMA<1>collides with data of the 2-nd dummy memory array DMA<2> may be prevented by the global switching part GSW.

In summary, in the semiconductor memory device of the second embodiment, the half of the 1-st dummy bit lines DBL_1 of the 1-st dummy memory array DMA<1> may be connected to the 1-st bit line sense amplifiers BSA_1 of the 1-st sense amplifier array SAR<1>, and the half of the 2-nd dummy bit lines DBL_2 of the 2-nd dummy memory array DMA<2> may be connected to the 3-rd bit line sense amplifiers BSA_3 of the 3-rd sense amplifier array SAR<3>.

In other words, the half of the 1-st dummy memory cells DMC<1> of the 1-st dummy memory array DMA<1> and the half of the 2-nd dummy cells DMC<2>of the 2-nd dummy memory array DMA<2>can store data.

As a result, according to the semiconductor memory device of the second embodiment, the degree of integration may be greatly improved.

The semiconductor memory device of the second embodiment may be modified in various forms.

### Third Embodiment

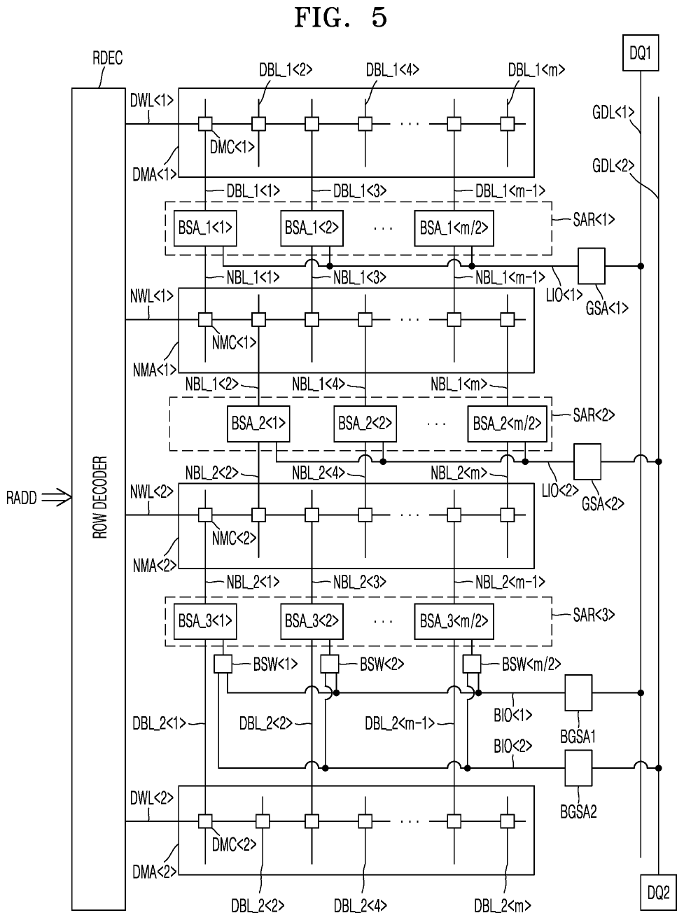

FIG. 5 is a schematic drawing illustrating a semiconductor memory device according to a third embodiment of the disclosure. Referring to FIG. 5, the semiconductor memory device of the second embodiment may include ‘n’ normal memory arrays. In the third embodiment, ‘n’ may be an even number greater than or equal to 2, and is ‘2’ in this specification.

For example, the semiconductor memory device of FIG. 5 may include 1-st to 2-nd normal memory arrays NMA<1:2>, a 1-st dummy memory array DMA<1>, a 2-nd dummy memory array DMA<2>, and 1-st to 3-rd sense amplifier arrays S AR<1:3>.

For example, 1-st to 2-nd normal memory arrays NMA<1:2> may be arranged side by side in serial order in one direction (vertical direction in FIG. 5). The 1-st dummy memory array DMA<1> may be disposed adjacent to an outer side (upper side in FIG. 5) of the 1-st normal memory array NMA<1>, and the 2-nd dummy memory array DMA<2> may be disposed adjacent to an opposite outer side (lower side in FIG. 5) of the 2-nd normal memory array NMA<2>.

In each of the 1-st to 2-nd normal memory arrays NMA<1:2>, the 1-st dummy memory array DMA<1>, and the 2-nd dummy memory array DMA<2>, one or more word lines may be disposed.

However, for ease of illustration, one word line is representatively shown and described in each of the 1-st to 2-nd normal memory arrays NMA<1:2>, the 1-st dummy memory array DMA<1>, and the 2-nd dummy memory array DMA<2>.

An i-th normal memory array NMA<i> may include i-th normal memory cells NMC<i>arranged on a matrix structure including an i-th normal word line NWL<i> and ‘na’ i-th normal bit lines NBL_i<1:m>. Here, ‘i’ may be a natural number from 1 to 2, and ‘na’ may be an even number greater than or equal to 2. For example, the i-th normal word line NWL<i> may be activated depending on the address value of a row address RADD.

The 1-st dummy memory array DMA<1> may include 1-st dummy memory cells DMC<1>arranged on a matrix structure including a 1-st dummy word line DWL<1> and ‘m’ 1-st dummy bit lines DBL_1<1:m>. For example, the 1-st dummy word line DWL<1> may be activated depending on the address value of the row address RADD.

The 2-nd dummy memory array DMA<2> may include 2-nd dummy memory cells DMC<2>arranged on a matrix structure including a 2-nd dummy word line DWL<2> and ‘na’ 2-nd dummy bit lines DBL_2<1:m>. For example, the 2-nd dummy word line DWL<2> may be activated depending on the address value of the row address RADD.

The 1-st amplifier array SAR<1> may include ‘m/2’ 1-st bit line sense amplifiers BSA_1, the 2-nd amplifier array SAR<2> may include ‘m/2’ 2-nd bit line sense amplifiers BSA_2, and 3-rd amplifier array SAR<3> may include ‘m/2’ 3-rd bit line sense amplifiers BSA_3.

For example, each of the 1-st bit line sense amplifiers BSA_1 of the 1-st sense amplifier array SAR<1> may be connected to a corresponding 1-st dummy bit line DBL_1 of the 1-st dummy memory array DMA<1> and a corresponding 1-st normal bit line NBL_1 of the 1-st normal memory array NMA<1>.

For example, each of the 1-st bit line sense amplifiers BSA_1 of the 1-st sense amplifier array SAR<1> may be driven to transmit and receive data with the corresponding 1-st dummy bit line DBL_1 of the 1-st dummy memory array DMA<1> in case that the 1-st dummy word line DWL<1> is activated.

Each of the 1-st bit line sense amplifiers BSA_1 of the 1-st sense amplifier array SAR<1> may be driven to transmit and receive data with the corresponding 1-st normal bit line NBL_1 of the 1-st normal memory array NMA<1> in case that the 1-st normal word line NWL<1> is activated.

Each of the 2-nd bit line sense amplifiers BSA_2 of a 2-nd sense amplifier array SAR<2> may be connected to a corresponding 1-st normal bit line NBL_1 of the j-st normal memory array NMA<1> and a corresponding 2-nd normal bit line NBL_2 of the 2-nd normal memory array NMA<2>.

For example, each of the 2-nd bit line sense amplifiers BSA_2 of a 2-nd sense amplifier array SAR<2> may be driven to transmit and receive data with the corresponding 1-st normal bit line NBL_1 of the 1-st normal memory array NMA<1> in case that a 1-st normal word line NWL<1> is activated.

Also, each of the 2-nd bit line sense amplifiers BSA_2 of a 2-nd sense amplifier array SAR<2> may be driven to transmit and receive data with the corresponding 2-nd normal bit line NBL_2 of the 2-nd normal memory array NMA<2> in case that a 2-nd normal word line NWL<2> is activated.

Each of the 3-rd bit line sense amplifiers BSA 3 of the 3-rd sense amplifier array SAR<3> may be connected to a corresponding 2-nd normal bit line NBL_2 of the 2-nd normal memory array NMA<2> and a corresponding 2-nd dummy bit line DBL_2 of the 2-nd dummy memory array DMA<2>.

For example, each of the 3-rd bit line sense amplifiers BSA_3 of the 3-rd sense amplifier array SAR<3> may be driven to transmit and receive data with the corresponding 2-nd normal bit line NBL_2 of the 2-nd normal memory array NMA<2> in case that the 2-nd normal word line NWL<2> is activated.

Each of the 3-rd bit line sense amplifiers BSA_3 of the 3-rd sense amplifier array SAR<3> may be driven to transmit and receive data with the corresponding 2-nd dummy bit line DBL_2 of the 2-nd dummy memory array DMA<2> in case that the 2-nd dummy word line DWL<2> is activated.

In this embodiment, any one of the 1-st bit line sense amplifiers BSA_1 of the 1-st sense amplifier array SAR<1> may be selected as a column address (not shown).

In case that the 1-st dummy memory array DMA<1> or the 1-st normal memory array NMA<1> is selected according to the row address RADD, the selected 1-st bit line sense amplifier BSA_1 may be driven to transmit and receive data with the 1-st data input/output pad DQ1 via a 1-st local data line LI0<1>, a 1-st global bit line sense amplifier GSA<1> and a 1-st global data line GDL<1>.

The 1-st global bit line sense amplifier GSA<1> may amplify data transmitted and received between the 1-st local data line LIO<1> and the 1-st global data line GDL<1>.

Any one of the 2-nd bit line sense amplifiers BSA_2 of the 2-nd sense amplifier array SAR<2> may be selected as a column address (not shown).

In case that the 1-st normal memory array NMA<1> or the 2-nd normal memory array NMA<2> is selected according to the row address RADD, the selected 2-nd bit line sense amplifier BSA_2 may be driven to transmit and receive data with the 2-nd data input/output pad DQ2 via a 2-nd local data line LIO<2>, a 2-nd global bit line sense amplifier GSA<2> and a 2-nd global data line GDL<2>.

The 2-nd global bit line sense amplifier GSA<2> may amplify data transmitted and received between the 2-nd local data line LIO<2> and the 2-nd global data line GDL<2>.

The semiconductor memory device according to the third embodiment may further include 1-st and 2-nd bottom data lines BI0<1> and BIO<2>, ‘m/2’ local switch part (or local switching unit) BSW, 1-st and 2-nd bottom sense amplifiers BGSA<1> and BGSA<2>, a 1-st global data line GDL<1> and a 2-nd global data line GDL<2>.

The 1-st bottom data line BI0<1> and the 2-nd bottom data line BIO<2>may be disposed between the 2-nd normal memory array NMA<2> and the 2-nd dummy memory array DMA<2>. The ‘m/2’ local switching part BSW may be disposed corresponding to the 3-rd bit line sense amplifiers BSA_3 of the 3-rd sense amplifier array SAR<3>.

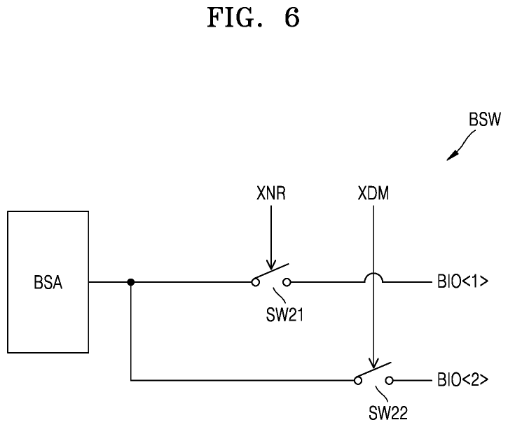

FIG. 6 is a schematic drawing illustrating one of the local switching parts BSW of FIG. 5. Referring to FIG. 6, the local switching part BSW may include 1-st and 2-nd local switches SW21 and SW22.

The 1-st local switch SW21 may be driven in response to activation of the normal signal XNR for the 1-st bottom data line BI0<1> to transmit and receive data with the bit line sense amplifier BSA. For example, the normal signal XNR may be activated according to the address value of the row address RADD at which the 2-nd normal word line NWL<2> of the 2-nd normal memory array NMA<2> may be activated.

The 2-nd local switch SW22 may be driven in response to activation of the dummy signal XDM for the 2-nd bottom data line BIO<2> to transmit and receive data with the bit line sense amplifier BSA. For example, the dummy signal XDM may be activated according to the address value of the row address RADD at which the 2-nd dummy word line DWL<2> of the 2-nd dummy memory array DMA<2>may be activated.

As a result, the local switching part BSW may be driven for the 1-st bottom data line BI0<1> to transmit and receive data with the bit line sense amplifier BSA in response to selection of the 2-nd normal word line NWL<2> of the 2-nd normal memory array NMA<2>.

The local switching part BSW may be driven for the 2-nd bottom data line BIO<2> to transmit and receive data with the bit line sense amplifier BSA in response to selection of the 2-nd dummy word line DWL<2> of the 2-nd dummy memory array DMA<2>.

Referring again to FIG. 5, any one of the 3-rd bit line sense amplifiers BSA_3 of the 3-rd sense amplifier array SAR<3> may be selected as a column address (not shown).

In case that the 2-nd normal memory array NMA<2> is selected according to the row address RADD, the selected 3-rd bit line sense amplifier BSA_3 may be driven to transmit and receive data with the 1-st data input/output pad DQ1 via the local switching part BSW, a 1-st bottom data line BI0<1>, a 1-st bottom sense amplifier BGSA<1> and a 1-st global data line GDL<1>.

In case that the 2-nd dummy memory array DMA<2> is selected according to the row address RADD, the selected 3-rd bit line sense amplifier BSA_3 may be driven to transmit and receive data with the 2-nd data input/output pad DQ2 via the local switching part BSW, a 2-nd bottom data line BIO<2>, a 2-nd bottom sense amplifier BGSA<2> and a 2-nd global data line GDL<2>.

The 1-st bottom sense amplifier BGSA<1> may amplify data transmitted and received between the 1-st bottom data line BI0<1> and the 1-st global data line GDL<1>selected according to the address value of the row address RADD. The 2-nd bottom sense amplifier BGSA<2> may amplify data transmitted and received between the 2-nd bottom data line BIO<2> and the 2-nd global data line GDL<2>selected according to the address value of the row address RADD.

The row address RADD may include multiple bits. The row decoder RDEC may decode the row address RADD to selectively activate the 1-st to the 2-nd normal word lines NVVL<1:2> and the dummy word lines DWL.

For example, the 1-st dummy word line DWL<1> and the 2-nd dummy word line DWL<2> may both be activated at the same address value of the row address RADD. In this case, a phenomenon in which data of the 1-st dummy memory array DMA<1>collides with data of the 2-nd dummy memory array DMA<2> may be prevented by the local switching part BSW.

In summary, in the semiconductor memory device of the third embodiment, the half of the 1-st dummy bit lines DBL_1 of the 1-st dummy memory array DMA<1> may be connected to the 1-st bit line sense amplifiers BSA_1 of the 1-st sense amplifier array SAR<1>, and the half of the 2-nd dummy bit lines DBL_2 of the 2-nd dummy memory array DMA<2> may be connected to the 3-rd bit line sense amplifiers BSA_3 of the 3-rd sense amplifier array SAR<3>.

In other words, the half of the 1-st dummy memory cells DMC<1> of the 1-st dummy memory array DMA<1> and the half of the 2-nd dummy cells DMC<2>of the 2-nd dummy memory array DMA<2>can store data.

As a result, according to the semiconductor memory device of the third embodiment, the degree of integration may be greatly improved.

While the disclosure has been described with reference to the embodiments shown in the drawings, these embodiments are merely illustrative and it should be understood that various modifications and other equivalent embodiments can be derived by those skilled in the art on the basis of the embodiments.

It will be apparent to those skilled in the art that various modifications can be made to the above-described embodiments of the disclosure without departing from the spirit or scope of the invention. Thus, it is intended that the disclosure covers all such modifications provided they come within the scope of the appended claims and their equivalents.

What is claimed is:

1. A semiconductor memory device comprising:
1-st to n-th normal memory arrays arranged side by side in a direction, wherein
an i-th normal memory array includes a plurality of i-th normal memory cells arranged in a matrix structure including an i-th normal word line and a plurality of i-th normal bit lines,
the i-th normal word line is activated depending on the address value of a row address;
a 1-st dummy memory array disposed adjacent to the 1-st normal memory array, and includes a plurality of 1-st dummy memory cells arranged in a matrix structure including a 1-st dummy word line and a plurality of 1-st dummy bit lines, wherein the 1-st dummy word line is activated depending on the address value of the row address;
a 2-nd dummy memory array disposed adjacent to the n-th normal memory array, and includes a plurality of 2-nd dummy memory cells arranged in a matrix structure including a 2-nd dummy word line and a plurality of 2-nd dummy bit lines, wherein the 2-nd dummy word line is activated depending on the address value of the row address; and
1-st to (n+1)-th sense amplifier array, wherein
the 1-st sense amplifier array includes a plurality of 1-st bit line sense amplifiers,
the j-th sense amplifier array includes a plurality of j-th bit line sense amplifiers, and
the (n+1)-th sense amplifier array includes a plurality of (n+1)-th bit line sense amplifiers, wherein
each of the plurality of 1-st bit line sense amplifiers of the 1-st sense amplifier array is electrically connected to a corresponding 1-st dummy bit line of the 1-st dummy memory array and a corresponding 1-st normal bit line of the 1-st normal memory array,
each of the plurality of i-th bit line sense amplifiers of the i-th sense amplifier array is electrically connected to a corresponding (i-1)-th normal bit line of the (i-1)-th normal memory array and a corresponding i-th normal bit line of the i-th normal memory array,
each of the plurality of (n+1)-th bit line sense amplifiers of the (n+1)-th sense amplifier array is connected to a corresponding n-th normal bit line of the n-th normal memory array and a corresponding 2-nd dummy bit line of the 2-nd dummy memory array,
‘n’ is an odd number greater than or equal to 1,
‘i’ is a natural number in a range of 1 to n,
‘j’ is a natural number in a range of 2 to n, and
‘p’ is a natural number in a range of 1 to (n+1)/2.

2. The semiconductor memory device of claim 1, wherein a plurality of (2p-1)-th bit line sense amplifiers of a (2p-1)-th sense amplifier array are driven to transmit and receive data with a 1-st data input/output pad.

3. The semiconductor memory device of claim 2, wherein a plurality of (2p)-th bit line sense amplifiers of a (2p)-th sense amplifier array are driven to transmit and receive data with a 2-nd data input/output pad.

4. The semiconductor memory device of claim 3, wherein the 1-st dummy word line of the 1-st dummy memory array and the 2-nd dummy word line of the 2-nd dummy memory array are selected in response to the address value of a same row address.

5. A semiconductor memory device comprising:
1-st to n-th normal memory arrays arranged side by side in a direction, wherein
an i-th normal memory array includes a plurality of i-th normal memory cells arranged in a matrix structure including an i-th normal word line and a plurality of i-th normal bit lines, and
the i-th normal word line is activated depending on the address value of a row address;
a 1-st dummy memory array disposed adjacent to the 1-st normal memory array, and includes a plurality of 1-st dummy memory cells arranged in a matrix structure including a 1-st dummy word line and a plurality of 1-st dummy bit lines, wherein the 1-st dummy word line is activated depending on the address value of the row address;
a 2-nd dummy memory array disposed adjacent to the n-th normal memory array, and includes a plurality of 2-nd dummy memory cells arranged in a matrix structure including a 2-nd dummy word line and a plurality of 2-nd dummy bit lines, wherein the 2-nd dummy word line is activated depending on the address value of the row address; and
1-st to (n+1)-th sense amplifier arrays, wherein
the 1-st sense amplifier array includes a plurality of 1-st bit line sense amplifiers,
the j-th sense amplifier array includes a plurality of j-th bit line sense amplifiers, and
the (n+1)-th sense amplifier array includes a plurality of (n+1)-th bit line sense amplifiers, wherein
each of the plurality of 1-st bit line sense amplifiers of the 1-st sense amplifier array is electrically connected to a corresponding 1-st dummy bit line of the 1-st dummy memory array and a corresponding 1-st normal bit line of the 1-st normal memory array,
each of the plurality of i-th bit line sense amplifiers of the i-th sense amplifier array is electrically connected to a corresponding (i-1)-th normal bit line of the (i-1)-th normal memory array and a corresponding i-th normal bit line of the i-th normal memory array,
each of the plurality of (n+1)-th bit line sense amplifiers of the (n+1)-th sense amplifier array is electrically connected to a corresponding n-th normal bit line of the n-th normal memory array and a corresponding 2-nd dummy bit line of the 2-nd dummy memory array,
‘n’ is an even number greater than or equal to 2,
‘i’ is a natural number in a range of 1 to n,
‘j’ is a natural number in a range of 2 to n, and
‘p’ is a natural number in a range of 1 to n/2.

6. The semiconductor memory device of claim 5, wherein a plurality of (2p-1)-th bit line sense amplifiers of a (2p-1)-th sense amplifier array are driven to transmit and receive data with a 1-st data input/output pad.

7. The semiconductor memory device of claim 6, wherein a plurality of (2p)-th bit line sense amplifiers of a (2p)-th sense amplifier array are driven to transmit and receive data with a 2-nd data input/output pad.

8. The semiconductor memory device of claim 7, wherein each of the plurality of (n+1)-th bit line sense amplifiers of the (n+1)-th sense amplifier array is driven to transmit and receive data with the 1-st data input/output pad in response to selection of one of the n-th normal bit lines of the n-th normal memory array, and driven to transmit and receive data with the 2-nd data input/output pad in response to selection of one of the 2-nd dummy bit lines of the 2-nd dummy memory array.

9. The semiconductor memory device of claim 8, wherein the 1-st dummy word line of the 1-st dummy memory array and the 2-nd dummy word line of the 2-nd dummy memory array are selected in response to the address value of a same row address.

10. The semiconductor memory device of claim 9, wherein the semiconductor memory device further includes:
a bottom data line disposed between the n-th normal memory array and the 2-nd dummy memory array, and transmitting and receiving data with the plurality of (n+1)-th bit line sense amplifiers of the (n+1)-th sense amplifier array;
a 1-st global data line transmitting and receiving data with the 1-st data input/output pad;
a 2-nd global data line transmitting and receiving data with the 2-nd data input/output pad; and
a global switching part,
wherein the global switching part is driven to transmit and receive data between the bottom data line and the 1-st global data line in response to selection of the n-th normal word line of the n-th normal memory array, and driven to transmit and receive data between the bottom data line and the 2-nd global data line in response to selection of the 2-nd dummy word line of the 2-nd dummy memory array.

11. The semiconductor memory device of claim 10, wherein
the semiconductor memory device further includes 1-st to 2-nd bottom data line disposed between the n-th normal memory array and the 2-nd dummy memory array, wherein
the 1-st bottom data line transmits and receives data with the 1-st data input/output pad, and
the 2-nd bottom data line transmits and receives data with the 2-nd data input/output pad,
each of the plurality of (n+1)-th bit line sense amplifiers of the (n+1)-th sense amplifier array is driven to transmit and receive data with the 1-st bottom data line in response to selection of one of the n-th normal bit lines of the n-th normal memory array, and driven to transmit and receive data with the 2-nd bottom data line in response to selection of one of the 2-nd dummy bit lines of the 2-nd dummy memory array.

12. A semiconductor memory device comprising:
1-st to n-th normal memory arrays arranged side by side in a direction, wherein
an i-th normal memory array includes a plurality of i-th normal memory cells arranged in a matrix structure including an i-th normal word line and a plurality of i-th normal bit lines, and
the i-th normal word line is activated depending on the address value of a row address;
a 1-st dummy memory array disposed adjacent to the 1-st normal memory array, and includes a plurality of 1-st dummy memory cells arranged in a matrix structure including a 1-st dummy word line and a plurality of 1-st dummy bit lines, wherein the 1-st dummy word line is activated depending on the address value of the row address;
a 2-nd dummy memory array disposed adjacent to the n-th normal memory array, and includes a plurality of 2-nd dummy memory cells arranged in a matrix structure including a 2-nd dummy word line and a plurality of 2-nd dummy bit lines, wherein the 2-nd dummy word line is activated depending on the address value of the row address; and
1-st to (n+1)-th sense amplifier arrays, wherein
the 1-st sense amplifier array includes a plurality of 1-st bit line sense amplifiers,
the j-th sense amplifier array includes a plurality of j-th bit line sense amplifiers, and
the (n+1)-th sense amplifier array includes a plurality of (n+1)-th bit line sense amplifiers, wherein
each of the plurality of 1-st bit line sense amplifiers of the 1-st sense amplifier array is electrically connected to a corresponding 1-st dummy bit line of the 1-st dummy memory array and a corresponding 1-st normal bit line of the 1-st normal memory array,
each of the plurality of i-th bit line sense amplifiers of the i-th sense amplifier array is electrically connected to a corresponding (i-1)-th normal bit line of the (i-1)-th normal memory array and a corresponding i-th normal bit line of the i-th normal memory array, and
each of the plurality of (n+1)-th bit line sense amplifiers of the (n+1)-th sense amplifier array is electrically connected to a corresponding n-th normal bit line of the n-th normal memory array and a corresponding 2-nd dummy bit line of the 2-nd dummy memory array,
‘n’ is a natural number greater than or equal to 2,
‘i’ is a natural number in a range of 1 to n, and
‘j’ is a natural number in a range of 2 to n.

13. The semiconductor memory device of claim 12, wherein the 1-st dummy word line of the 1-st dummy memory array and the 2-nd dummy word line of the 2-nd dummy memory array are selected in response to the address value of a same row address.

14. The semiconductor memory device of claim 13, further comprising:
1-st and 2-nd bottom data lines;
‘n/2’ local switch part;
1-st and 2-nd bottom sense amplifiers; and
a 1-st global data line and a 2-nd global data line.

15. The semiconductor memory device of claim 14, wherein the local switching part is driven for the 1-st bottom data line to transmit and receive data with the plurality of (n+1) bit line sense amplifiers in response to selection of the i-th normal word line of the i-th normal memory array.

16. The semiconductor memory device of claim 15, wherein the local switching part is driven for the 2-nd bottom data line to transmit and receive data with the (n+1) bit line sense amplifiers in response to selection of the i-th dummy word line of the i-th dummy memory array.
